(19) United States
(12) Patent Application Publication
(10) Pub. No.: US 2004/0021586 A1
(43) Pub. Date: Feb. 5, 2004

(54) Keyboard scanner with error rejection

(76) Inventor: Wenkwei Lou, San Diego, CA (US)

Correspondence Address: GARLICK HARRISON & MARKISON LLP, P.O. BOX 160727, AUSTIN, TX, 78716-0727, US

(21) Appl. No.: 10/329,824

(22) Filed: Dec. 26, 2002

Related U.S. Application Data
(60) Provisional application No. 60/399,959, filed on Jul. 31, 2002.

(51) Int. Cl. H03M 11/00; H03K 17/94

(52) U.S. Cl. 341/26; 341/22

(57) ABSTRACT

An improved method and apparatus for scanning a keyboard matrix. A switch matrix having a plurality of rows and columns is operably connected to a wireless interface device for use with a wirelessly enabled host. Switch transition circuitry generates an output signal upon detection of a transition in the voltage level of at least one row in the switch matrix from a first state to a second state. Control circuitry latches the state of the columns and rows in the switch matrix upon detection of a voltage transition by the switch transition circuitry and scan logic scans the rows and columns of the switch matrix to detect operation of at least one switch in the switch matrix by testing the state of all columns latched in a high state. Control circuitry operating in cooperation with the scan logic and the driver logic change the state of the columns from a first state to a second state to detect the state of an associated row in the switch matrix. A control signal is applied to selected columns to force the selected columns to the first state after detecting the state of the associated rows, thereby decreasing the amount of time required to test the state of the columns.

### CROSS REFERENCE TO RELATED APPLICATION

This application claims priority to U.S. Provisional Application Serial No. 60/399,959, filed Jul. 31, 2002, which is incorporated herein by reference in its entirety for all purposes.

### BACKGROUND

1. Technical Field

The present invention relates generally to digital computers; and more particularly to wireless interfaces for allowing user input devices to communicate with digital computers.

2. Related Art

There are many user input devices for use with a digital computer, including standard keyboards, touchpads, mice and trackballs. Wireless communication technology has advanced rapidly over the past few years and there has been rapid development of wireless technologies for providing communication between input/output devices and their “host” computers. For example, wireless keyboards and mice now couple via wireless connections to their host computers. These “wireless” input devices are highly desirable since they do not require any hard-wired connections with their host computers. However, the lack of a wired connection also requires that the wireless input devices contain their own power supply, i.e., that they be battery powered.

In order to extend the life of its batteries, a wireless input devices often supports power saving modes of operation. For example, a wireless interface may include circuitry to provide for various levels of “power-down” modes to reduce power consumption when the device is inactive. When activity is detected, the interface circuitry will transition to a powered-up mode to facilitate communications between the user interface device and the computer and will then return to a power-down mode after a predetermined interval of inactivity of the user interface device.

To obtain maximum power conservation it is important to minimize the amount of time that the interface circuitry must remain in a powered-up mode. Traditional methods of scanning input devices, such as keyboards, are comparatively inefficient and result in significantly reduced battery life for wireless input devices.

Thus, there is a need in the art for a method and apparatus for decreasing the amount of time to complete a scan of a user input device to thereby allow a wireless input device to operate for an extended period on a single battery life.

### SUMMARY OF THE INVENTION

The present invention provides an improved method and apparatus for scanning a keyboard matrix with improved error rejection. Specifically, the present invention significantly reduces the amount of time needed to scan a keyboard matrix and thereby significantly reduces the amount of power needed to operate the associated circuitry over an extended period of time. The apparatus of the present invention is broadly comprised of a switch matrix that is operably connected to a wireless interface device for use with a wirelessly enabled host. The apparatus is further comprised of switch transition circuitry operable to generate an output signal upon detection of a transition in the voltage level of at least one row in the switch matrix from a first state to a second state; control circuitry operable to latch the state of the columns and rows in the switch matrix upon detection of a voltage transition by the switch transition circuitry; and scan logic operably connected to the switch matrix to scan the rows and columns of the switch matrix, wherein the scanning circuit detects operation of at least one switch in the switch matrix by testing the state of all columns latched in a high state. Control circuitry operating in cooperation with the scan logic and the driver logic change the state of the columns from a first state to a second state to detect the state of an associated row in the switch matrix. A control signal is applied to selected columns to force the selected columns to the first state after detecting the state of the associated rows, thereby decreasing the amount of time required to test the state of the columns.

The method of the present invention comprises the steps of applying control signals to the rows and columns of the switch matrix to place the rows and columns in a predetermined state; detecting a transition in the voltage level of at least one row in the switch matrix from a first state to a second state; latching the state of all columns in the matrix; scanning the rows and columns of the switch matrix, to detect operation of at least one switch in the switch matrix by testing the state all columns latched in a high state; changing the state of the columns from a first state to a second state to detect the state of an associated row in the switch matrix; and applying a control signal to selected columns to force the selected columns to the first state after detection of the state of the associated rows, thereby decreasing the time required to test the state of the columns.

### BRIEF DESCRIPTION OF THE DRAWINGS

FIG. 1A is a system diagram illustrating a PC host and a wireless mouse that includes a wireless interface device constructed according to the present invention;

FIG. 1B is a system diagram illustrating a PC host and a wireless keyboard that includes a wireless interface device constructed according to the present invention;

FIG. 2 is a schematic block diagram illustrating the structure of a wireless mouse that includes a wireless interface device constructed according to the present invention;

FIG. 3 is a schematic block diagram illustrating the structure of a wireless keyboard that includes a wireless interface device constructed according to the present invention;

FIG. 4 is a block diagram illustrating a wireless interface device (integrated circuit) constructed according to the present invention;

FIG. 5 is a block diagram illustrating a wireless interface unit of the wireless interface device of FIG. 4;

FIG. 6 is a block diagram illustrating a processing unit of the wireless interface device of FIG. 4;

FIG. 7 is a block diagram illustrating an input/output unit of the wireless interface device of FIG.4;

FIG. 8 is a block diagram generally showing the structure of an integrated circuit constructed according to the present invention with particular detail in the coupling of battery power to the units of the device;

FIG. 9 is a logic diagram illustrating operation according to the present invention; and

FIG. 10 is a logic diagram illustrating operation according to the present invention in controlling the power consumption of a serviced device.

FIG. 11 is an illustration of the keyboard scan circuit components according to the present invention.

FIG. 12 is a timing diagram illustrating operation of the keyboard matrix circuitry operating in a first mode.

FIG. 13 is a flowchart illustration of the data processing steps carried out in accordance with the timing diagram of FIG. 12.

FIG. 14 is a timing diagram illustrating operation of the keyboard matrix circuitry operating in a second mode to identify a plurality of activated keys on a keyboard matrix.

### DETAILED DESCRIPTION

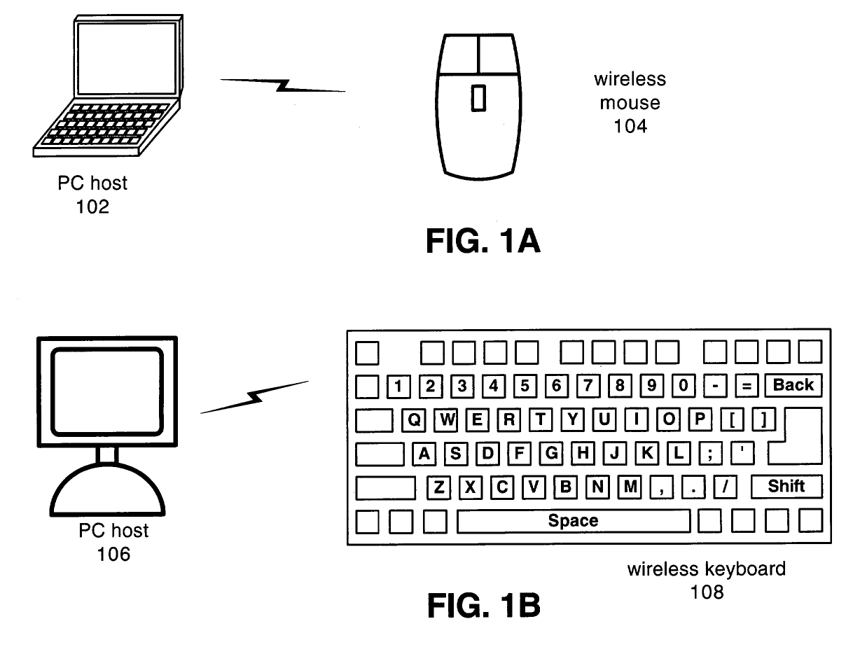

FIG. 1A is a system diagram illustrating a PC host 102 and a wireless mouse 104 that includes a wireless interface device constructed according to the present invention. As shown in FIG. 1A, the PC host 102 wirelessly couples to the wireless mouse 104. In the structure of FIG. 1A, the wireless mouse 104 includes a wireless interface device that operates to place the wireless mouse in any of a number of reduced power operating modes, including a power down mode in which battery life is substantially extended.

FIG. 1B is a system diagram illustrating a PC host 106 and a wireless keyboard 108 that includes a wireless interface device constructed according to the present invention. The wireless keyboard 108 is battery powered and operates for extended periods of time on a single set of batteries because of the greatly reduced power consumption operations according to the present invention.

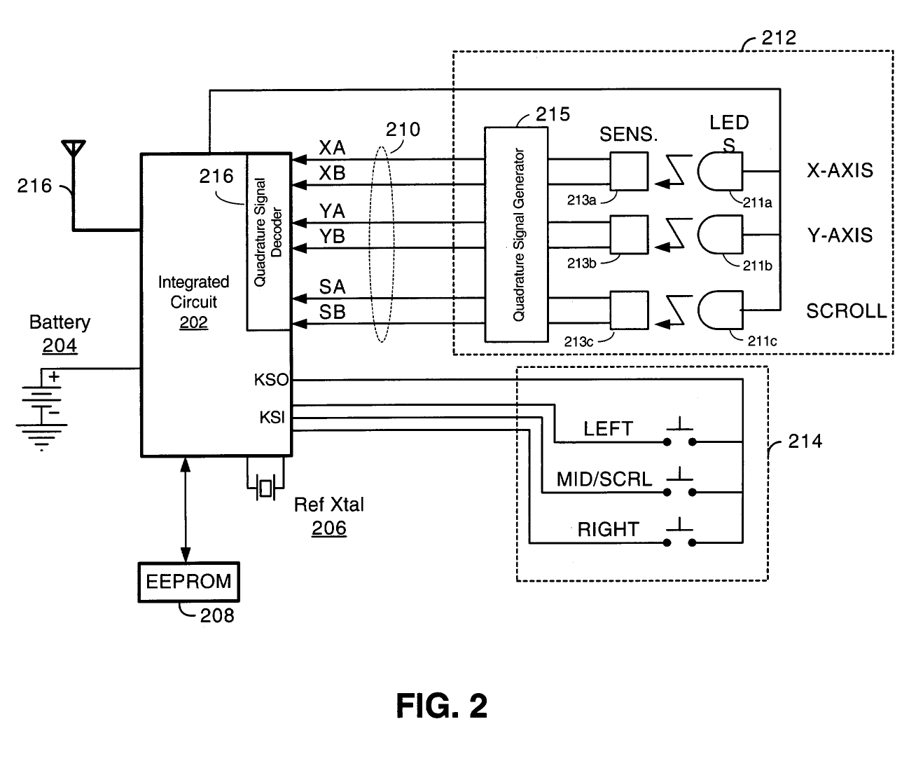

FIG. 2 is a schematic block diagram illustrating the structure of a wireless mouse that includes a wireless interface device constructed according to the present invention. An integrated circuit 202 constructed according to the present invention serves as the wireless interface device and couples to various mouse inputs 210. These mouse inputs 210 include x-axis and y-axis inputs as well as a scroll input. The x-axis and y-axis inputs are often referred to a “quadrature” inputs. The components that produce the quadrature inputs are generally referred to at numeral 212 and may be constructed from optical inputs instead of from conventional mechanical inputs. Referenced via numeral 214 are the button inputs that are typical with a computer mouse and include the left button input, the middle/scroll button input, and the right button input. As is shown, each of the signals produced by the mouse is received by integrated circuit 202.

Integrated circuit 202 also couples to battery 204, crystal 206 that produces a reference frequency, EEPROM 208, and antenna 216. In one embodiment of the present invention, battery 204 comprises a pair of either AA batteries or AAA batteries. Antenna 216 is an internal antenna because of the size constraints of the mouse and because of the relatively short distance between the PC host and the wireless mouse.

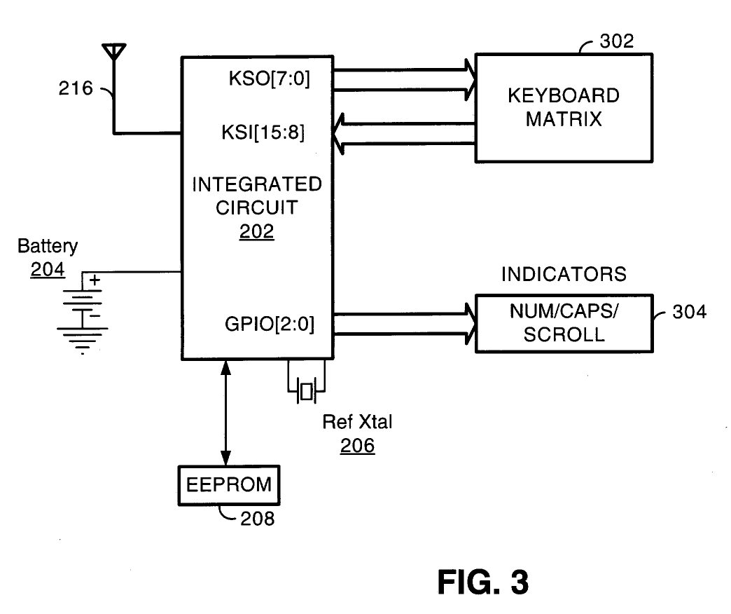

FIG. 3 is a schematic block diagram illustrating the structure of a wireless keyboard matrix 302 that operates in conjunction with a wireless interface device (integrated circuit 202) constructed according to the present invention. As shown in FIG. 3, integrated circuit 202 services a key scan matrix 302 that provides inputs from the keyboard. Indicators 304 include number, capitals, and scroll lights that are lit on the keyboard. The integrated circuit 202 couples to a battery 204, a crystal 206, an EEPROM 208, and an antenna 216.

In another embodiment (not shown in either FIG. 2 or FIG. 3), the integrated circuit 202 services both mouse and keyboard input and may reside internal to either the mouse or the keyboard. As will be apparent to those skilled in the art, multiplexing or signal sharing may be required, because the input signals differ. However, different signal lines may be dedicated for keyboard and for mouse inputs such that no signal sharing is required. As is apparent, when the integrated circuit 202 alone services both mouse and keyboard input wired connectivity between the keyboard and the mouse is required.

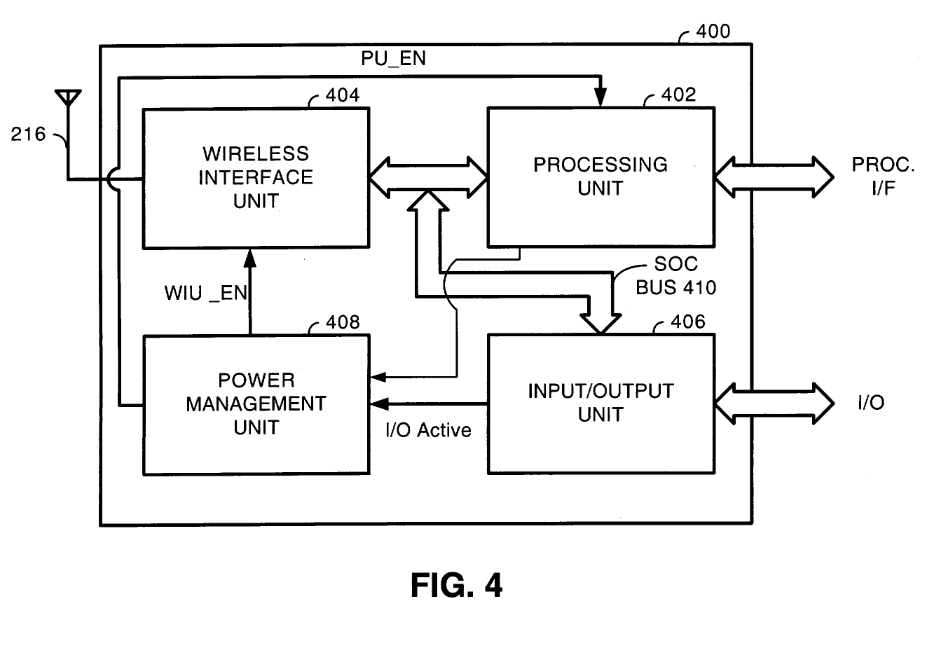

FIG. 4 is a block diagram illustrating a wireless interface device (integrated circuit) constructed according to the present invention. As shown in FIG. 4, the wireless interface device 400 includes a processing unit 402, a wireless interface unit 404, an input/output unit 406, and a power management unit 408. The wireless interface unit 404 couples the wireless interface device 400 to antenna 216. The wireless interface unit 404 can be adapted to operate according to the Bluetooth specification and in particular to the Human Interface Device (HID) portion of the Bluetooth specification. It will be understood by those skilled in the art, however, that the present invention can be adapted to work in conjunction with other wireless interface standards.

Processing unit 402, wireless interface unit 404, and input/output unit 406 couple with one another via a system on a chip (SOC) bus 410. Processing unit 402 includes a processing interface that may be used to couple the processing unit to one or more devices. Input/output unit 406 includes an input/output set of signal lines that couple the wireless interface device 400 to at least one user input device, such as a mouse or the keyboard.

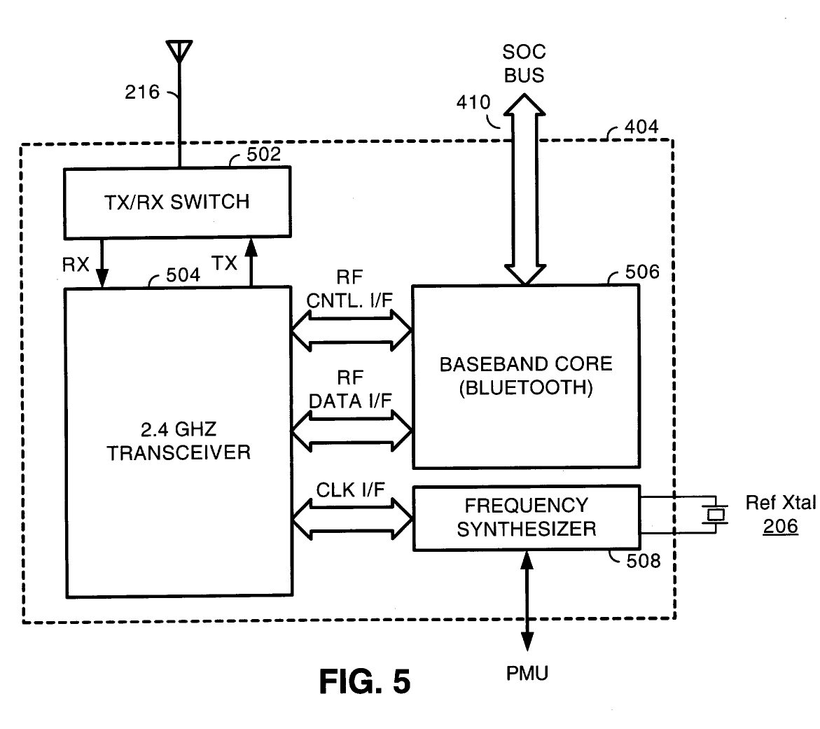

FIG. 5 is a block diagram illustrating a wireless interface unit of the wireless interface device of FIG. 4. The wireless interface unit 404 includes a transmit/receive switch 502, a 2.4 GHz transceiver 504, a baseband core 506 which may be compatible with the Bluetooth standard, and a frequency synthesizer 508. Each of these components is generally known in the field and will be described in minimal detail herein.

The transmit/receive switch 502 couples to antenna 216 and switches between transmit and receive operations. The 2.4 GHz transceiver 504 performs all RF front-end operations and operates within a frequency band and on particular channels as are specified by the Bluetooth operating standard. The 2.4 GHz transceiver 504 couples to baseband core 506. Such coupling is performed via an RF control interface and an RF data interface. The RF control interface performs the necessary control operations to guaranty that the 2.4 GHz transceiver 504 and the baseband core 506 will operate consistently with desired operating specifications. The RF data interface transfers both Rx and Tx data between the 2.4 GHz transceiver 504 and the baseband core 506. Frequency synthesizer 508 couples to the power management unit 408, to the external crystal 206 and to the 2.4 GHz transceiver 504. The frequency synthesizer 508 is controlled to provide an RF frequency for the 2.4 GHz transceiver 504 which is used to mix with the baseband signal received from the baseband core during a transmit operation and to mix with the received RF signal during a receive operation. The baseband core 506 couples to other wireless interface devices via the SOC bus 410.

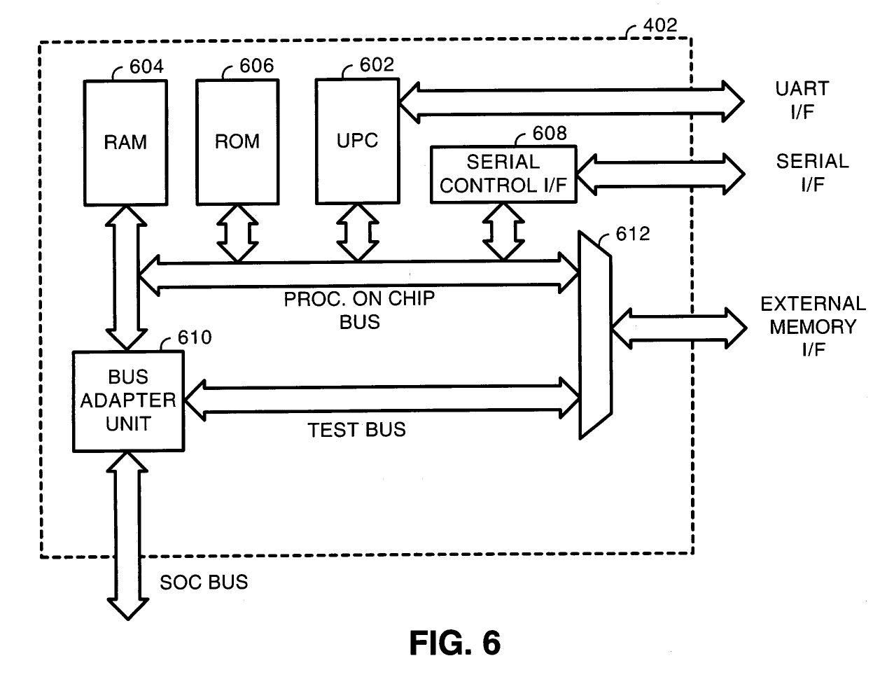

FIG. 6 is a block diagram illustrating a processing unit 402 of the wireless interface device of FIG. 4. The processing unit 402 includes a microprocessor core 602, read only memory 606, random access memory 604, serial control interface 608, bus adapter unit 610, and multiplexer 612. The microprocessor core 602, ROM 606, RAM 604, serial control interface 608, bus adapter unit 610, and multiplexer 612 couple via a processor on a chip bus. Multiplexer 612 multiplexes an external memory interface between the processor on a chip bus and a test bus. The bus adapter unit 610 interfaces the processor on a chip bus with the SOC bus. The microprocessor core 602 includes a universal asynchronous receiver transmitter interface that allows direct access to the microprocessor core. Further, the serial control interface 608 provides a serial interface path to the processor on a chip bus.

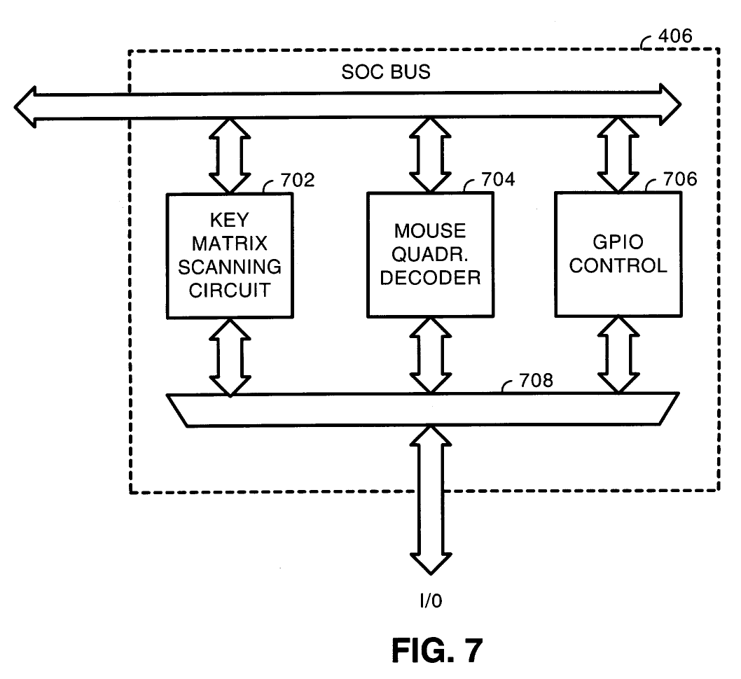

FIG. 7 is a block diagram illustrating an input/output unit 406 of the wireless interface device of FIG. 4. The input/output unit 406 includes a keyboard scanning block 702, a mouse quadrature decoder block 704, and a GPIO control block 706. Each of the keyboard scanning block 702, the mouse quadrature decoder block 704, and the GPIO control block 706 couple to the SOC bus. Further, each of the keyboard scanning block 702, the mouse quadrature decoder block 704, and the GPIO control block 706 couple to I/O via multiplexer 708. This I/O couples to at least one user input device.

In another embodiment of the input/output unit 406, each of the keyboard scanning block 702, the mouse quadrature decoder block 704, and the GPIO control block 706 couples directly to external pins that couple to at least one user input device.

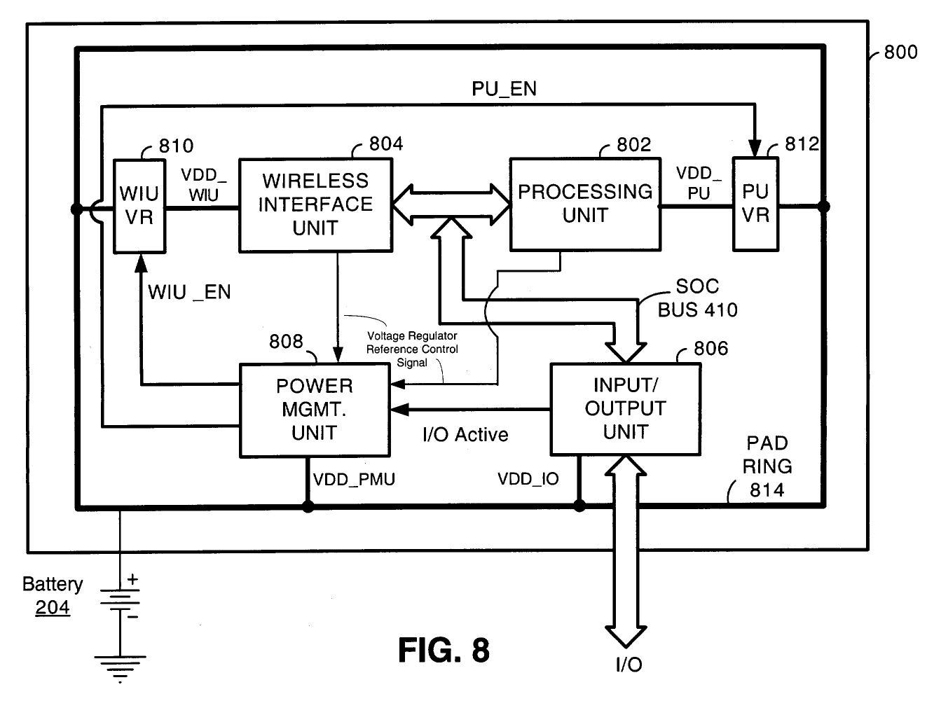

FIG. 8 is a block diagram generally showing the structure of an integrated circuit constructed according to the present invention with particular detail in the coupling of battery power to the units of the device. Integrated circuit 800 of FIG. 8 includes a wireless interface unit 804, processing unit 802, input/output unit 806, and power management unit 808. The processing unit 802, wireless interface unit 804, and input/output unit 806 couple via a SOC bus 410. Further, as was previously described, input/output unit 806 couples to at least one user input device via I/O connection.

With the integrated circuit 800 of FIG. 8, a pad ring 814 surrounds a substantial portion of the components of the integrated circuit. The pad ring 814 couples directly to battery 204, which powers the pad ring. Further, input/output unit 806 and power management unit 808 couple directly to pad ring 814 to receive their power and voltage. However, processing unit 802 couples to pad ring 814 via processing unit voltage regulation circuitry 812. Further, the wireless interface unit 804 couples to pad ring 814 via wireless interface unit voltage regulation circuitry 810. The processing unit voltage regulation circuitry 812 is controlled by the power management unit 808 via control signal PU_EN. Further, the wireless interface unit voltage regulation circuitry 810 is controlled by the power management unit 808 using control signal WIU_EN.

The integrated circuit operates in four different power-conserving modes: (1) busy mode; (2) idle mode; (3) suspend mode; and (4) power down mode. Busy mode, idle mode, and suspend mode are described in the Bluetooth specification. However, power down mode is unique to the present invention.

In busy mode, the Master (host computer) is actively polling the HID (wireless mouse, wireless keyboard, etc.) for data at a polling rate near 100 polls/second, or about once every 16 slot times. Continued user activity (keypad strokes, mouse motion, button presses, etc.) keeps the HID in busy mode. If there has been no activity for a few seconds (determined by particular settings), operation transitions to idle mode.

In idle mode, the HID requests the master (serviced host) to enter SNIFF mode with a SNIFF interval that is chosen based on desired latency and average power consumption. In one operation, the SNIFF interval is 50 ms, or about every 80 slot times. Although the HID can transition to I/O Active immediately after an event, it may have to wait up to 100 mS to transmit its data to the host, and therefore must have enough buffer space to store 100 mS of events. If an event occurs, the HID requests the master to leave SNIFF mode. If there is no further activity for a longer period, the HID transitions from idle mode to suspend mode. Then, the HID is parked.

In suspend mode, a longer beacon interval can be used for a lower power state. When in suspend mode, any user input detected will result in the HID requesting to be unparked and transitioned back to the busy mode. When the HID is parked, it consumes less power than when the host is in SNIFF mode since the HID does not have to transmit. In suspend mode, the HID just listens to the beacons to remain synchronized to the master's frequency hopping clock. As long as the master continues transmitting (meaning the host is not turned off) the HID will remain in suspend mode. If link loss occurs due to the host being turned off without warning, or the host moving out of range, the Lost Link state will be entered.

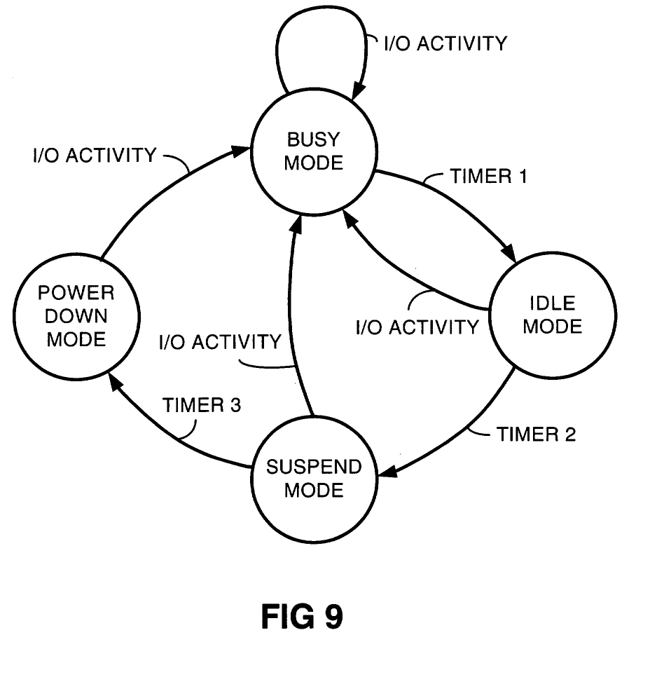

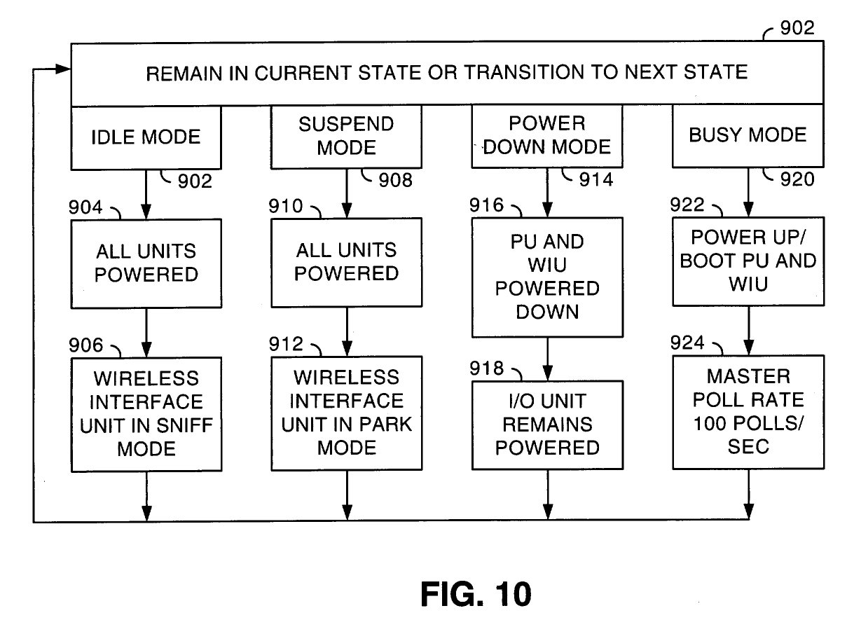

According to the present invention, the power down mode is also supported. In the power down mode, the power management unit 808 operates the processing unit voltage regulation circuitry 812 and the wireless interface unit voltage regulation circuitry 810 to power down the processing unit 802 and wireless interface unit 804, respectively. These states of operation will be described further with reference to FIGS. 9 and 10.

FIG. 9 is a logic diagram illustrating operation according to the present invention. As illustrated in FIG. 9, a wireless interface device operating according to the present invention operates in four separate power-conserving modes. These power conservation modes include the busy mode, the idle mode, the suspend mode and, the power down mode. The state diagram of FIG. 9 shows how each of these modes is reached during normal operation.

When the wireless interface device is initially powered up, it enters the busy mode of operation. In the busy mode of operation, all features and wireless operations of the wireless interface device are enabled. As long as I/O activity continues, the wireless interface device remains in the busy mode. However, after expiration of a first timer with no I/O activity, the operation moves from the busy mode to the idle mode. Operation will remain in idle mode until the expiration of a second timer or until I/O activity occurs.

If while in the idle mode I/O activity occurs, operation returns to the busy mode. If in the idle mode, if timer 2 expires with no additional I/O activity, suspend mode is entered. While in suspend mode, if I/O activity occurs, operation returns to busy mode. However, if in suspend mode, no additional I/O activity occurs until the expiration of a third timer, power down mode is entered. While in the power down mode, operation will remain in the power down mode until I/O activity occurs. When I/O activity occurs, operation of the wireless interface device will move from the power down mode to the busy mode.

FIG. 10 is a logic diagram illustrating operation according to the present invention in controlling the power consumption of a serviced device. As shown in FIG. 10, once operation in a particular power conservation state, e.g., busy mode, idle mode, suspend mode, and power down mode has commenced, operation will remain in that state until expiration of respective timer or I/O activity occurs (step 902).

When power conservation operation occurs to move from the busy mode to the idle mode (step 902), all portions of the wireless interface device remain powered (step 904). However, in the idle mode, the wireless interface unit enters a sniff mode in which some of its operations are reduced. Such operations were previously described with reference to FIG. 9. Further, additional information regarding this mode is available in the Bluetooth HID standard.

When the operation of the wireless interface device transitions from the idle mode to the suspend mode (step 908) all portions of the wireless interface device remain powered (step 910). However, the wireless interface unit of the wireless interface device enters the park mode, which consumes even less power than does the wireless interface unit when in the sniff mode.

When in the suspend mode if an additional timer or inactivity period expires, the wireless interface device will transition to the power down mode (step 914). In the power down mode, the processing unit and wireless interface unit will be powered down (step 916). This power down operation will be performed in one embodiment by simply disconnecting a voltage source from the processing unit and the wireless interface unit. One such technique for doing this is described with reference to FIG. 8. In the power down mode, the input/output unit 406 will continue to be powered to allow it to sense the state of the user input device lines.

Finally, from any of the reduced power operating states, when I/O activity is sensed by the input/output unit 406, the wireless input device will transition back to the busy mode (step 920). When such operation occurs, if the components have been powered down, they will be powered up and will go through their boot operations (step 922). Then, in the busy mode, the wireless interface unit will operate in its normal state in which the master wireless device, i.e., wirelessly enabled host will poll the wireless interface device at 100 times per second. From each of steps 906, 912, 918, and 924, operation returns to step 902 wherein the current power conservation state will be kept until another event occurs.

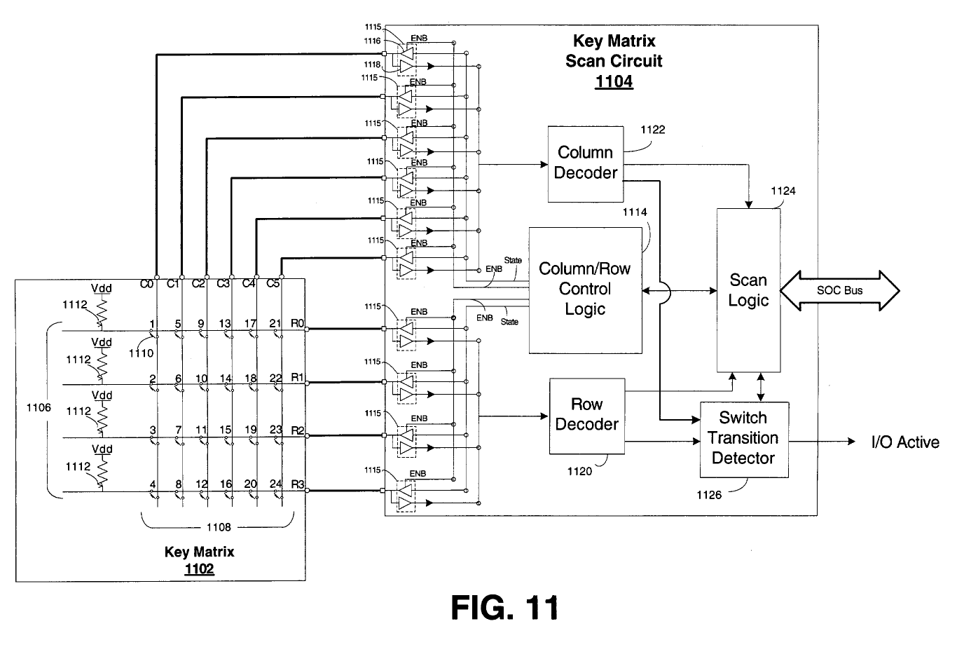

FIG. 11 is an illustration of a keyboard switch matrix 1102 connected to a key matrix scan circuit 1104. The keyboard matrix 1102 comprises a plurality of columns 1108 and a plurality of rows 1106. In the embodiment shown in FIG. 11, the plurality of columns 1108 comprises six columns C0-C5 and the plurality of rows comprises four rows, R0-R3. The embodiment illustrated in FIG. 11 shows only a small portion of an actual keyboard matrix and it is understood by those skilled in the art that the number of rows and columns can be increased or decreased depending on the specific application.

A plurality of switches 1110 connect the respective rows and columns when a corresponding key is pressed by a user. In the illustration of FIG. 11, switch 1110 connects row R0 and column C0 when the switch 1110 is pressed. Although a reference numeral has not been provided for each of the switches, it should be understood that a total of 24 switches 1110 are associated with the intersection of the rows and columns in FIG. 11. For purposes of discussion, the twenty-four illustrative switches 1110 in FIG. 11 will be referred to as Switch 1, Switch 2, . . . , Switch 24. When all of the respective switches in a particular row are open, the row will be pulled “high” by resistor 1112 that is connected to Vdd. Rows R0-R3 provide inputs to row decoder 1120 in the key matrix scan circuit 1104, as will be discussed in greater detail below.

Key matrix scan circuit 1104 comprises column/row control logic 1114 and driver logic 1115 that generate appropriate signals to control the state of the respective columns and rows. Driver logic 1115 comprises a tri-state driver 1116 and a buffer 1118. The column/row control logic 1114 generates appropriate “high” and “low” signals that are provided to the inputs of the tri-state drivers 1116. The column/row control logic can change the state of a particular row or column by generating appropriate “enable” signals that control the operation of the tri-state drivers 1116 in the control logic 1115. For example, if the input of the tri-state driver 1116 is “high,” the generation of an enable signal will cause the tri-state driver 1116 to apply the “high” signal at its output to drive the column or row “high.” Conversely, if the input to the tri-state driver 1116 is “low,” the generation of an enable signal will cause that tri-state driver to drive the column or row “low.” The enable signals can be global enable signals intended to enable the tri-state drivers for all rows, e.g. ENB_R, or for all columns, e.g. ENB_C. The enable signals also can be directed to a tri-state driver for a particular row, e.g. ENB_R1, or for a particular column, e.g. ENB_C3.

The key matrix scan circuit 1104 also comprises row decoder 1120 and column decoder 1122 that are operable to decode output signals received from the respective rows and columns in the keyboard matrix 1102. The decoded output signals from the row decoder 1120 and the column decoder 1122 are provided to scan logic 1124 which generates a data stream indicating the state of various switches (keys) 1110.

The key matrix scan circuit 1104 also comprises a switch transition detection circuit 1126 that receives output signals from the row decoder 1120 and the column decoder 1122. The switch transition detection circuit 1126 is communicatively coupled to the scan logic 1124 which scans the various rows and columns as described hereinbelow. In addition, the switch transition detection circuit 1126 generates an “I/O Active” signal that is provided to the input/output unit 406 to cause the system to transition into the “busy” mode as described herein.

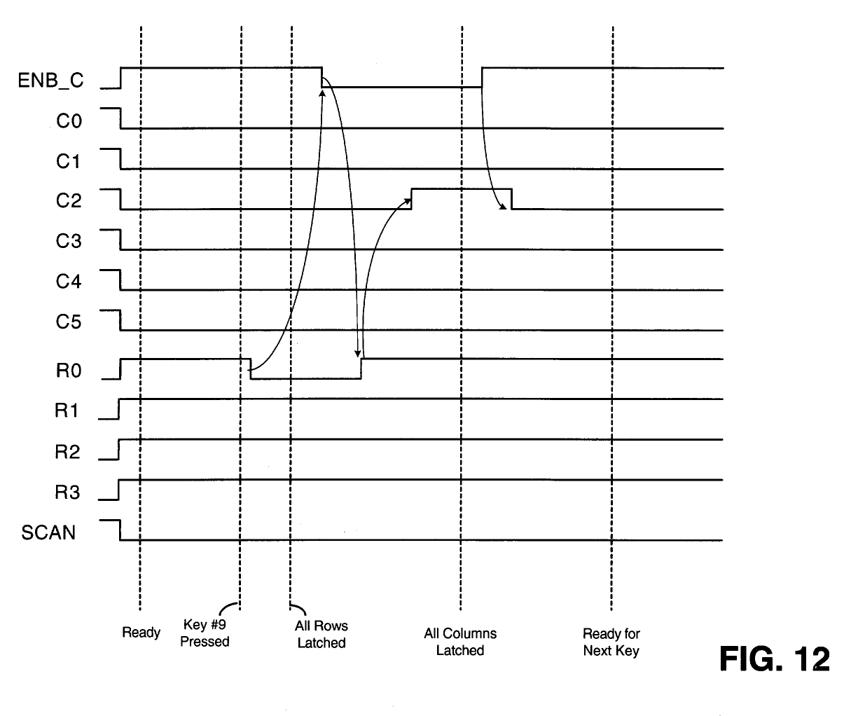

Operation of the keyboard scan circuitry can be understood by referring to the timing diagrams of FIGS. 12-14. Referring to FIG. 12, the initial state of all of the rows and columns is analyzed beginning at the “Ready” reference line. The transitions to the left of the “Ready” reference are provided simply to clarify the “high” or “low” status of the rows and columns when processing begins. Beginning at the “Ready” reference point, ENB_C is high (active) and all columns are driven low. All of the rows are pulled high via the resistors 1112 shown in FIG. 11.

If, as an example, Key #9 is pressed, R0 transitions from “high” to “low.” This transition is used as a trigger to latch (store) all row values. This transition also causes ENB_C to transition from “high” to “low.” Since ENB_C is “low,” the columns are no longer being driven and, therefore, R0 transitions back to “high.” The actual transition of R0 to “high” will be delayed somewhat by the RC constant combination of the line capacitance of column C2 and the resistor 1112. Since switch #9 is still pressed, the column C2 will transition to “high.” The “low” to “high” transition of column C2 is used as a trigger to latch all column values. After the column values have been latched, ENB_C transitions from “low” to “high” and column C2 transitions from “high” to “low.” All other columns are also maintained in the “low” state since ENB_C is now high (active).

In the example shown in FIG. 12, there is one high latched column value (C2) and one low latched row value (R0). The single latched column and the single latched row uniquely identify a single key switch (switch #9) and, therefore, there is no need to enter into a “scan” of other rows and columns. Thus the scan signal remains “low” during the entire cycle.

The column/row control logic 1114, in conjunction with the driver logic 1115, is operable to generate all of the control signals necessary to control the state transitions described above. Furthermore, the switch transition detection circuit 1126 is operable to generate an “I/O Active” signal for the input/output unit 406 immediately upon receiving an output signal from the row decoder 1120 and/or the column decoder 1122 indicating that a switch has been activated. In this example the “I/O Active” signal will be generated immediately by the switch transition detection circuit 1126 immediately upon detection of the transition of row R0 from “high” to “low” as a result of switch #9 being activated.

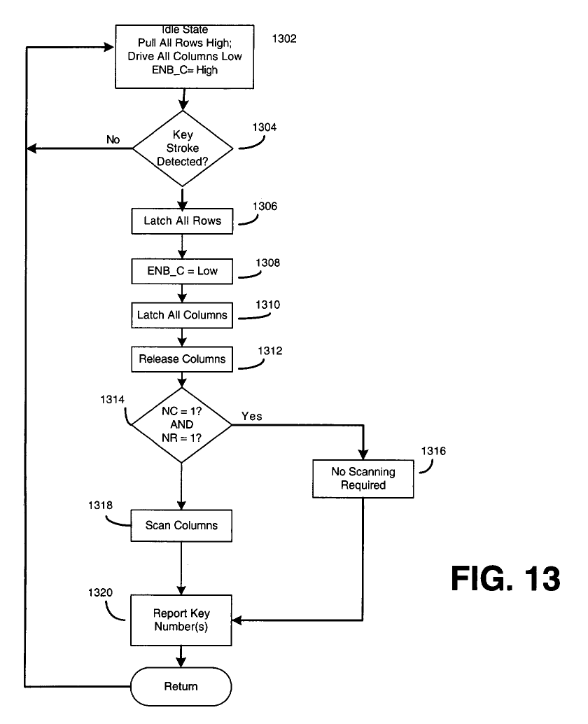

FIG. 13 is a flowchart representation of the generalized signal processing steps to identify which key has been pressed. In step 1302, the system is in the idle state. ENB_C is set to “high;” all columns are driven “low” and all rows are pulled “high.” In step 1304, the system determines whether a key stroke has been detected (i.e., a row has transitioned to “low”). If no key stroke is detected, processing returns to the idle state in step 1302. If a key stroke is detected in step 1304, however, the rows are latched in step 1306 and ENB_C is set to “low” in step 1308. In step 1310 the columns are “latched” and in step 1312 the columns are released. In step 1314 the system determines whether the number of columns is equal to 1 and the number of rows is equal to 1. If this condition is met, processing proceeds to step 1316 indicating that no scanning is needed because the keys that were pressed have been uniquely identified and these keys are reported in step 1320. If, however, the test in step 1314 indicates that the number of columns is greater than 1 or the number of rows is greater than 1, processing proceeds to step 1318 where the columns are scanned as discussed in greater detail below. After the scanning process has been completed, the key numbers are reported in step 1320 and processing returns to the idle state in step 1302.

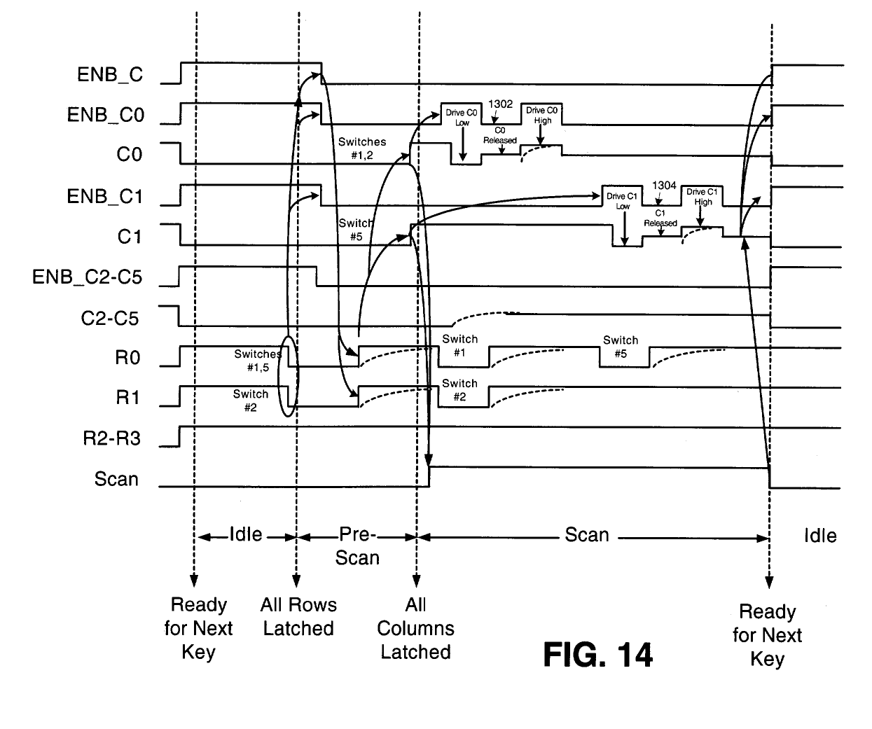

Operation of the scan mode can be understood by referring to the timing diagram of FIG. 14. The initial state of all of the rows and columns is analyzed beginning at the “Ready” reference line. Again, the transitions to the left of the “Ready” reference are provided simply to clarify the “high” or “low” status of the rows and columns when processing begins. Beginning at the “Ready” reference point ENB_C is high (active) and all columns are, therefore, driven low. All of the rows are pulled high via the resistors 1112 shown in FIG. 11.

If, as an example, key #1, key #2, and key #5 are pressed, R0 and R1 transition from “high” to “low.” These transitions are used as a trigger to latch (store) all row values. This transition also causes ENB_C to transition from “high” to “low.” In addition ENB_C0, ENB_C1 and ENB_C2-5 will also transition from “high” to “low.” Since ENB_C is “low,” the columns are no longer being driven “low” and, therefore, R0 and R1 transition back to “high.” The actual transition of R0 and R1 to “high” will be delayed somewhat by the RC constant combination of the line capacitance of columns C0 and C1 and the resistors 1112. Since switch #1, switch #2 and switch #5 are still pressed, the columns C0 and C1 will transition to “high.” The “low” to “high” transition of columns C0 and C1 are used as a trigger to latch all column values. Two columns, C0 and C1 are latched in the high state.

Because the column decoder 1122 and the row decoder 1120 determine that more than one column has been latched, and more than one row has been latched, the system enters scan mode and the SCAN signal goes “high” and the scan begins for the two columns, C0 and C1, latched in the “high” condition. First, ENB_C0 is driven “high” and column C0 is driven low. With C0 driven low, the rows corresponding to activated switches will be driven low because the activated switch connects those rows to C0. In this example, switch #1 causes R0 to be driven low and switch #2 causes R1 to be driven low. The transition of rows R0 and R1 is detected by the row decoder 1120 and the scan logic 1124 to indicate that the switches corresponding to C0 and rows R0 and R1 are activated, thereby identifying that switch#1 and switch #2 are activated. ENB_C0 then makes a transition from “high” to “low” as illustrated by reference numeral 1302 and, therefore, C0 is released, i.e., no longer driven “low.” Rows R0 and R1, therefore, transition from “low” to “high,” although the actual transition of R0 and R1 to “high” will be delayed somewhat by the RC constant combination of the line capacitance of columns C0, C1 and the resistors 1112. Column C0 also begins a transition to the “high” state; however, this transition is also delayed by RC constant combination of the line capacitance of the column and the resistors. The duration of the time interval that ENB_C0 remains “low” is programmable (controlled by the column/row control logic 1114) and can range from zero (0) cycles to a few cycles, e.g. 1-3 cycles. In the case where ENB_C0 is driven “low” for one or more cycles, the “low” cycle illustrated by reference numeral 1302 will be followed by a transition of ENB_C0 to the “high” state whereby a control signal generated by the column/row control logic 1114 will be applied via the driver 1116 to drive column C0 “high” rapidly. If the duration of the “low” cycle represented by reference numeral 1302 is 0 cycles, ENB_C0 will not transition to the “low” state after the determination of which rows transitioned to the “low” state. In this case, ENB_C0 will remain “high” while the column/row control logic 1114 generates a signal causing the driver 1116 to drive column C0 high. This causes column C0 to rise rapidly to a “high” state. Under either of the above-discussed sequences, the rapid transition of column C0 to the “high” state increases the efficiency of the scanning process by decreasing the amount of time that the scanning circuitry must draw power for the operation.

Scanning continues with ENB_C1 following a sequence similar to that discussed above in connection with C0. ENB_C1 transitions from “low” to “high,” thus driving C1 “low.” With C1 driven low, the rows corresponding to activated switches will be driven low because the activated switch connects those rows to C1. In this example, switch #5 causes R0 to be driven low. The transition of row R0 is detected by the row decoder 1120 and the scan logic 1124 to indicate that the switch corresponding to C1 and row R0 is activated, thereby identifying that switch #5 is activated. ENB_C1 then makes a transition from “high” to “low” and, therefore, C1 is released, i.e., is no longer driven “low.” Row R0, therefore, transitions from “low” to “high.” The actual transition of R0 to “high” will be delayed somewhat by the RC constant combination of the line capacitance of column C1 and the resistor 1112. Column C1 also begins a transition to the “high” state; however, this transition is also delayed by RC constant combination of the line capacitance of the column and the resistors. As discussed above, the duration of the time interval that ENB_C1 remains “low” is programmable (controlled by the column/row control logic 1114) and can range from zero (0) cycles to a few cycles, e.g. 1-3 cycles. In the case where ENB_C1 is driven “low” for one or more cycles, the “low” cycle illustrated by reference numeral 1304 will be followed by a transition of ENB_C1 to the “high” state whereby a control signal generated by the column/row control logic 1114 will be applied via the driver 1116 to drive column C1 “high” rapidly. If the duration of the “low” cycle represented by reference numeral 1304 is 0 cycles, ENB_C1 will not transition to the “low” state after the determination of which rows transitioned to the “low” state. In this case, ENB_C1 will remain “high” while the column/row control logic 1114 generates a signal causing the driver 1116 to drive column C1 high. This causes column C1 to rise rapidly to a “high” state. Again, under either of the above-discussed sequences, the rapid transition of column C1 to the “high” state increases the efficiency of the scanning process by decreasing the amount of time that the scanning circuitry must draw power for the operation. With the scan of the columns completed, the scan logic will have reported switch #1, switch #2 and switch #5 as active. The system then returns to the “Ready” state.

The invention disclosed herein is susceptible to various modifications and alternative forms. Specific embodiments, therefore, have been shown by way of example in the drawings and detailed description. It should be understood, however, that the drawings and detailed description thereto are not intended to limit the invention to the particular form disclosed, but on the contrary, the invention is to cover all modifications, equivalents and alternatives falling within the spirit and scope of the present invention as defined by the claims.

1. A user input device comprising:
a switch matrix having a plurality of rows and columns;
driver logic to apply control signals to the rows and columns of the switch matrix;
scan logic operably connected to the switch matrix to scan the rows and columns of the switch matrix, wherein the scan logic detects operation of at least one switch in the switch matrix by testing the state of all columns latched in a high state; and
control circuitry operating in cooperation with the scan logic and the driver logic to:
change the state of the columns from a first state to a second state to detect the state of an associated row in the switch matrix; and
apply a control signal to selected columns to force the selected columns to the first state after detection of the state of the associated rows, thereby decreasing the time required to test the state of the columns.

2. The user input device of claim 1, wherein the columns latched in a high state uniquely correspond to activation of a single switch in the switch matrix.

3. The user input device of claim 1, wherein the columns latched in a high state correspond to an ambiguous plurality of switches.

4. The user input device of claim 3, wherein the scan logic identifies a plurality of columns associated with the plurality of switches and sequentially scans each of the plurality of columns to resolve the ambiguity and thereby identify activation of an unambiguous plurality of switches.

5. The user input device of claim 1, wherein the switch transition circuitry generates an I/O activation signal upon detection of a switch transition.

6. The user input device of claim 5, wherein the I/O activation signal causes the user input device to transition from a low power state to a busy state.

7. A method of detecting an input to a key switch matrix on a user input device, said switch matrix having a plurality of columns and rows, comprising:
applying control signals to the rows and columns of the switch matrix to place the rows and columns in a predetermined state;
detecting a transition in the voltage level of at least one row in the switch matrix from a first state to a second state;
latching the state of all columns in the matrix;
scanning the rows and columns of the switch matrix, to detect operation of at least one switch in the switch matrix by testing the state all columns latched in a high state;
changing the state of the columns from a first state to a second state to detect the state of an associated row in the switch matrix; and
applying a control signal to selected columns to force the selected columns to the first state after detection of the state of the associated rows, thereby decreasing the time required to test the state of the columns.

8. The method of claim 7, wherein the columns latched in a high state uniquely correspond to activation of a single switch in the switch matrix.

9. The method of claim 7, wherein the columns latched in a high state correspond to an ambiguous plurality of switches.

10. The method of claim 9, further comprising identifying a plurality of columns associated with the plurality of switches and sequentially scanning each of the plurality of columns to resolve the ambiguity and thereby identify activation of an unambiguous plurality of switches.

11. The method of claim 7, further comprising generating an I/O activation signal upon detection of a transition in the voltage level of at least one row.

12. The method of claim 11, further comprising using the I/O activation signal to cause a wireless interface operably connected to the key switch matrix to transition from a low power state to a busy state.

13. A system for detecting an input to a key switch matrix on a user input device, said switch matrix having a plurality of columns and rows, comprising:
means for applying control signals to the rows and columns of the switch matrix to place the rows and columns in a predetermined state;
means for detecting a transition in the voltage level of at least one row in the switch matrix from a first state to a second state;
means for latching the state of all columns in the matrix;
means for scanning the rows and columns of the switch matrix, to detect operation of at least one switch in the switch matrix by testing the state all columns latched in a high state;
means for changing the state of the columns from a first state to a second state to detect the state of an associated row in the switch matrix; and
means for applying a control signal to selected columns to force the selected columns to the first state after detection of the state of the associated rows, thereby decreasing the time required to test the state of the columns.

14. The system of claim 13, wherein the columns latched in a high state uniquely correspond to activation of a single switch in the switch matrix.

15. The system of claim 13, wherein the columns latched in a high state correspond to an ambiguous plurality of switches.

16. The system of claim 15, further comprising means for identifying a plurality of columns associated with the plurality of switches and means for sequentially scanning each of the plurality of columns to resolve the ambiguity and thereby identify activation of an unambiguous plurality of switches.

17. The system of claim 13, further comprising means for generating an I/O activation signal upon detection of a transition in the voltage level of at least one row.

18. The system of claim 17, further comprising means for detecting the I/O activation signal to signal a wireless interface operably connected to the key switch matrix to transition from a low power state to a busy state.

19. A system that services communications between a wirelessly enabled host and at least one user input device, comprising:
a wireless interface unit that wirelessly interfaces with the wirelessly enabled host;
a processing unit operably coupled to the wireless interface unit;
an input/output unit operably coupled to the wireless interface unit and to the processing unit, wherein the input/output unit also operably couples to the user input device;
a power management unit operably coupled to the wireless interface unit, the processing unit, and the input/output unit, wherein the power management unit controls the power consumption of the system; and
a user input device, comprising:
a switch matrix having a plurality of plurality of rows and columns;
driver logic to apply control signals to the rows and columns of the switch matrix;
scan logic operably connected to the switch matrix to scan the rows and columns of the switch matrix, wherein the scanning circuit detects operation of at least one switch in the switch matrix by testing the state all of columns latched in a high state; and
control circuitry operating in cooperation with the scan logic and the driver logic to:
change the state of the columns from a first state to a second state to detect the state of an associated row in the switch matrix; and
apply a control signal to selected columns to force the selected columns to the first state after detection of the state of the associated rows, thereby decreasing the time required to test the state of the columns.

20. The system of claim 19, wherein the columns latched in a high state uniquely correspond to activation of a single switch in the switch matrix.

21. The system of claim 19, wherein the columns latched in a high state correspond to an ambiguous plurality of switches.

22. The system of claim 21, wherein the scan logic identifies a plurality of columns associated with the plurality of switches and sequentially scans each of the plurality of columns to resolve the ambiguity and thereby identify activation of an unambiguous plurality of switches.

23. The system of claim 19, wherein the power management unit powers down the wireless interface unit and the processing unit after at least one inactivity period during which the user input device is inactive with respect to the input/output unit.

24. The system of claim 19, wherein the power management unit controls the power consumption of the system by:
powering down the wireless interface unit and the processing unit during reduced power operations; and
based upon notification received from the input/output unit indicating activity by the user input device, powering up the wireless interface unit and the processing unit.

25. The system of claim 24, wherein the system enters one of a plurality of power consumption operating states comprising:
busy mode in which all components of the wireless interface device are powered and operational;
idle mode in which the wireless interface unit performs first power conserving operations;
suspend mode in which the wireless interface unit performs second power conserving operations; and
power down mode in which the wireless interface unit and the processing unit are powered down.

26. The system of claim 19, wherein the switch transition circuitry generates an I/O activation signal upon detection of a switch transition.

27. The system of claim 23, wherein the I/O activation signal causes the system to transition from a low power state to a busy state.
